(19) United States
(12) Patent Application Publication
(10) Pub. No.: US 2025/0132195 A1
(43) Pub. Date: Apr. 24, 2025

(54) METHODS AND FORMULATIONS FOR SACRIFICIAL BRACING, SURFACE PROTECTION, AND QUEUE-TIME MANAGEMENT USING STIMULUS RESPONSIVE POLYMERS

(71) Applicant: Lam Research Corporation, Fremont, CA (US)

(72) Inventors: Stephen M. SIRARD, Austin, TX (US); Gregory BLACHUT, Campbell, CA (US); Diane HYMES, San Jose, CA (US)

(21) Appl. No.: 18/695,337

(22) PCT Filed: Sep. 26, 2022
(86) PCT No.: PCT/US2022/044750

§ 371 Date: Mar. 25, 2024

Related U.S. Application Data
(60) Provisional application No. 63/248,980, filed on Sep. 27, 2021.

(51) Int. Cl. H01L 21/768; B05D 1/00; H01L 21/67

(52) U.S. Cl. CPC H01L 21/76814; B05D 1/60; H01L 21/67098; H01L 21/76816; B05D 2320/00; B05D 2518/00

(57) ABSTRACT

Methods of bracing high aspect ratio (HAR) structures include coating the HAR structures with stimulus responsive polymers (SRP) films followed by baking the SRP films at a temperature above the glass transition temperature (Tg) of the SRP film and below the degradation temperature of the SRP. In some embodiments, the SRP film includes a plasticizer.

### INCORPORATION BY REFERENCE

A PCT Request From is filed concurrently with this specification as part of the present application. Each application that the present application claims benefit of priority to as identified in the concurrently filed PCT Request Form is incorporated by reference herein in their entireties and for all purposes.

### BACKGROUND

During semiconductor fabrication, many surfaces are sensitive to airborne molecular contaminants (AMCs) in the surrounding environment. Queue time can lead to exposure to the AMCs and unwanted interactions such as oxidation, corrosion, and halogenation. Solutions include storing partially fabricated semiconductor substrates in nitrogen (N₂)-filled storage cassettes or rooms and using integrated tools that support multiple processes without breaking the vacuum on the substrates. These solutions are difficult and expensive to implement and pose safety and reliability concerns.

Furthermore, as semiconductor devices continue to scale down to smaller sizes, higher aspect ratio structures are used to achieve the desired device performance. The fabrication of semiconductor devices involves multiple iterations of processes such as material deposition, planarization, feature patterning, feature etching, and feature cleaning. The drive towards higher aspect ratio structures creates processing challenges for many of these traditional fabrication steps. Wet processes such as etch and clean, which may make up greater than 25% of the overall process flow, are particularly challenging on high aspect ratio (HAR) features due to the capillary forces that are generated during drying. The strength of these capillary forces depends on the surface tension and contact angle of the etch, clean, or rinse fluids that are being dried, as well as the feature spacing and aspect ratio. If the forces generated during drying are too high, then the high aspect ratio features will collapse onto each other and stiction may occur. Feature collapse and stiction will severely degrade the device yield.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure relates to a method including providing a substrate with an SRP film thereon, wherein the SRP film comprises a stimulus responsive polymer (SRP), the SRP characterized by a ceiling temperature (Tc) at which the SRP is in thermal equilibrium with its monomers, the Tc being between −80° C. and 400′C; and baking the SRP film at a baking temperature, wherein the baking temperature is above a glass transition temperature the SRP film and below a degradation temperature of the SRP.

In some embodiments, the SRP is amorphous. In some embodiments, the SRP is semi-crystalline and crystalline and the baking temperature is above a melting temperature of the SRP film.

In some embodiments, the substrate has a high aspect ratio (HAR) structure having gaps formed between features and wherein the SRP film is provided in the gaps. In some such embodiments, baking the SRP film straightens the HAR structure.

In some embodiments, providing the substrate with the SRP film comprises spin coating an SRP formulation on the substrate. In some such embodiments, the substrate has a high aspect ratio (HAR) structure, the HAR structure including gaps formed between features. Spin coating the SRP formulation on the substrate comprises filling the gaps with the SRP film and bending the features of the HAR structure. In some such embodiments, baking the SRP film straightens the features of the HAR structure.

In some embodiments, the SRP film comprises a plasticizer. In some such embodiments, the (mass of plasticizer/mass of SRP)*100 is between 1 and 35. In some embodiments, (mass of plasticizer/mass of SRP)*100 is less than 10.

In some embodiments, the SRP comprises a poly(phthalaldehyde) or a derivative thereof as a homopolymer or as one of the constituent polymers of a copolymer. In some such embodiments, the SRP film comprises a phthalate plasticizer.

In some embodiments, the method further comprises removing the SRP film. In some such embodiments, removing the SRP film comprises exposing the SRP film to a stimulus depolymerize the SRP film. Examples of stimuli include heat, UV radiation, acidic vapor, and noble gas plasma.

In some embodiments, the SRP film comprises an organic weak acid. In some embodiments, providing a substrate with an SRP film thereon includes depositing the SRP film by chemical vapor deposition. In some embodiments, the SRP does not comprise a plasticizer.

Another aspect of the disclosure relates to an apparatus including a chamber for housing a substrate with an SRP film thereon, wherein the SRP film comprises a stimulus responsive polymer (SRP), the SRP characterized by a ceiling temperature (Tc) at which the SRP is in thermal equilibrium with its monomers, the T_{c} being between −80° C. and 400° C.; and a controller comprising instructions for baking the SRP film at a baking temperature, wherein the baking temperature is below a degradation temperature of the SRP and above a glass transition temperature of the SRP film. In some embodiments, the instructions further include instructions for depositing the SRP film. The SRP film may be deposited in the same or different chamber as the SRP is baked in.

These and other aspects of the disclosure are discussed further below with reference to the drawings.

### BRIEF DESCRIPTION OF DRAWINGS

FIG. 1A is a flow diagram showing an example of a method of bracing high aspect ratio (HAR) structure using a stimulus responsive polymer (SRP).

FIG. 1B is a flow diagram showing an example of a method of protecting a sensitive surface during semiconductor process using an SRP.

FIG. 2 shows a schematic example of operations in a method of bracing a HAR structure using an SRP.

FIGS. 3A and 3B are a flow diagrams showing examples of methods of removing a SRP from a structure.

FIG. 4 is a functional block diagram of an example of a substrate processing system including multiple substrate processing tools and a storage buffer according to the present disclosure.

FIG. 5 shows images of an SRP solution in a HAR structure after operations in methods described herein.

### DETAILED DESCRIPTION

Stimuli responsive polymers (SRPs) may be used in semiconductor fabrication processes for sacrificial bracing of high aspect ratio (HAR) structures and queue-time extension.

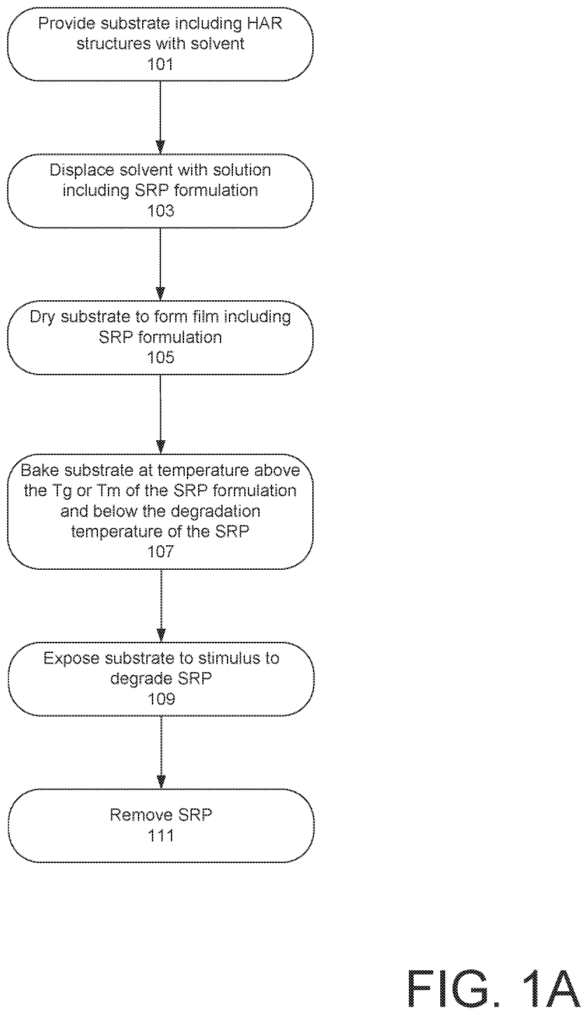

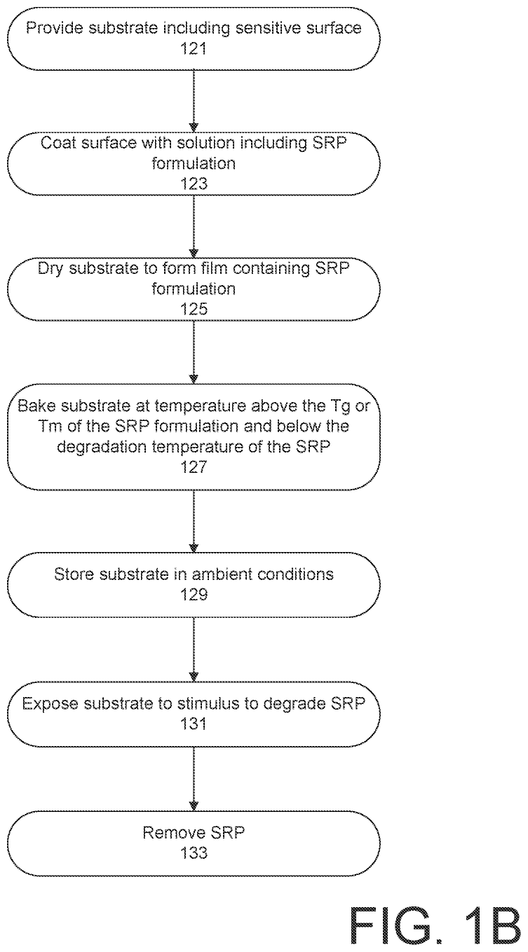

Referring to FIG. 1A, an example of a method for bracing HAR structures using an SRP is shown. First at an operation 101, a substrate including HAR structures with a solvent is provided. HAR structures are structures having high aspect ratios (ARs), e.g., at least 8, 10, 20, 30, 40, or 80. The substrate may be provided, for example, after a wet etch or cleaning operation and have solvent associated with the prior operation. In some embodiments, the solvent in operation 101 may be a transitional solvent if the prior solvent is not chemically compatible with the SRP solution.

Next in an operation 103, the solvent is displaced with a solution that includes a stimuli responsive polymer (SRP) formulation. The substrate is then dried in an operation 105. The SRP formulation precipitates out of solution and fills the HAR structures with a SRP film. Operations 103 and 105 can involve a spin coating process in which a solution including the SRP in a solvent is cast onto the substrate, followed by spinning to spread the solution, and evaporation of the solvent by airflow.

The substrate is then baked at a temperature above the glass transition temperature (Tg) or melting temperature (Tm) of the SRP film and below the degradation temperature of the SRP in an operation 107. Baking may be performed in the same or different chamber as the previous operations. Example baking times may range from 10 seconds to 300 seconds. The baking relaxes stress on the HAR structures and/or reduces voids in the filled structures.

The substrate is then exposed to a stimulus, such as light, heat, plasma, or chemistry that degrades the SRP in an operation 109. In some embodiments, operation 109 involves controlled exposure to a compound or to two reactants that react to form a compound that degrades the SRP. The stimulus is any compound that scissions bonds of the SRP to degrade it. In some embodiments, the compound is a relatively strong acid or base. Monomers or fragments from the degraded polymer remaining on the substrate can then be further removed from the structure in an operation 111. In some embodiments, exposure to metastable species from a noble gas plasma is performed during operations 109 and/or 111.

SRPs may also be used in the semiconductor fabrication processes for transient protection of a sensitive surface of substrate. This in turn can extend available queue time. FIG. 1B shows an example of a method for protection of a sensitive surface of a substrate. At operation 121, a substrate including an environmentally sensitive surface is provided. The surface may be a planar surface or include one or more pillars, holes, and trenches, including HAR structures. Examples of substrate surfaces that can be sensitive to environmental queue time effects include silicon, silicon germanium, and germanium structures such as fins and nanowires, metal surfaces including but not limited to copper, titanium, titanium nitride, cobalt, tungsten or molybdenum, and/or other structures and materials.

The surface is then coated with a solution including an SRP formulation in an operation 123. The substrate is then dried in an operation 125, forming a protective SRP film including SRP on the sensitive substrate. The substrate is then baked at a temperature above the glass transition temperature (Tg) or melting temperature (Tm) of the SRP film and below the degradation temperature of the SRP in an operation 127. The use of Tg or Tm depends on whether the SRP is amorphous or not. Films of amorphous SRPs, which are characterized by a Tg, are baked above the Tg of the SRP film. An example of an amorphous SRP is poly(phthaldehyde)-co-ethanal. Films of crystalline or semi-crystalline SRPs, which are characterized by both a Tg and a Tm, are baked above the Tm of the SRP film as well as above the Tg of the SRP film. An example of a semi-crystalline SRP is polyoxymethylene. Baking may be performed in the same or different chamber as the previous operations. The baking may reduce voids in the coated film. The substrate can then be stored in ambient conditions in an operation 129. When ready for further processing, the substrate is exposed to a stimulus, such as light, heat, or a chemistry that degrades the SRP in an operation 131. Volatile monomers or fragments from the degraded polymer can then be removed from the structure in an operation 133.

In alternate embodiments, operations 101-105 in FIG. 1A and, more particularly, operations 121-125 in FIG. 1B may be replaced with chemical vapor deposition (CVD) of an SRP. CVD deposition of SRPs is described in PCT/US2021/40009 incorporated by reference herein. CVD deposition of an SRP can be implemented by inletting one or precursor gases for the SRP to a processing chamber. In some examples, two or more different precursors are used to make a copolymer film. A copolymer may be a random or block copolymer. In addition, initiators and/or catalysts can also be supplied. Using a substrate processing system that performs CVD or iCVD, a polymer film is deposited onto a substrate to protect the exposed surface of the substrate from modification by oxygen, water, halogens, or other reactive species to minimize variability associated with the queue period in between process steps. The polymer film is removed prior to a downstream process. In some examples, the polymer film is removed by heating the substrate under vacuum to a temperature greater than or equal to 80° C. and less than or equal to 600° C., or less than equal to 400° C. In some examples, the polymer film includes polyaldehydes (sometimes called polyacetals), where the polymer backbone includes alternating carbon-oxygen bonds. These polymer films have a low ceiling temperature and will readily revert back to a monomeric form when exposed to a sufficiently high temperature. Examples of these types of polymer film include polyoxymethylene and polyacetaldehyde that can be deposited using a dry CVD or iCVD process as well as using a spin-on process. In some examples, the precursors for the polymer film include monomeric aldehyde or a precursor with alternating carbon-oxygen ring structures such as 1,3,5-trioxane or paraldehyde. Examples of monomeric aldehydes include formaldehyde, ethanal, propanal, butanal, pentanal, hexanal, heptanal, octananal, nonanal, or decanal, and any non-linear (branched) versions of these molecules. Other examples of polymer films include polypropionaldehyde, polybutyraldehyde, polyvaleraldehyde, and polyheptaldehyde, and copolymers of these aforementioned homopolymers, for example polyoxymethylene-r-polyacetaldehyde. In some embodiments, the precursors are combined over the substrate. For example, an energy source such as a heated wire filament or a hot surface are used to activate one or more of the precursors. In some examples, the substrate is cooled below a temperature of other surfaces in the processing chamber to promote adsorption of the precursors, or condensation of the polymer film, onto the substrate. In other examples, the substrate is heated to a predetermined temperature to promote the polymerization reaction. Deposition using CVD may be implemented in particular for a method as shown in FIG. 1B.

FIGS. 1A and 1B are flow diagrams showing certain operations in example semiconductor fabrication processes that use SRPs, though the methods described herein are not limited to particular applications but may be used with any application in involving coating SRP films on surfaces.

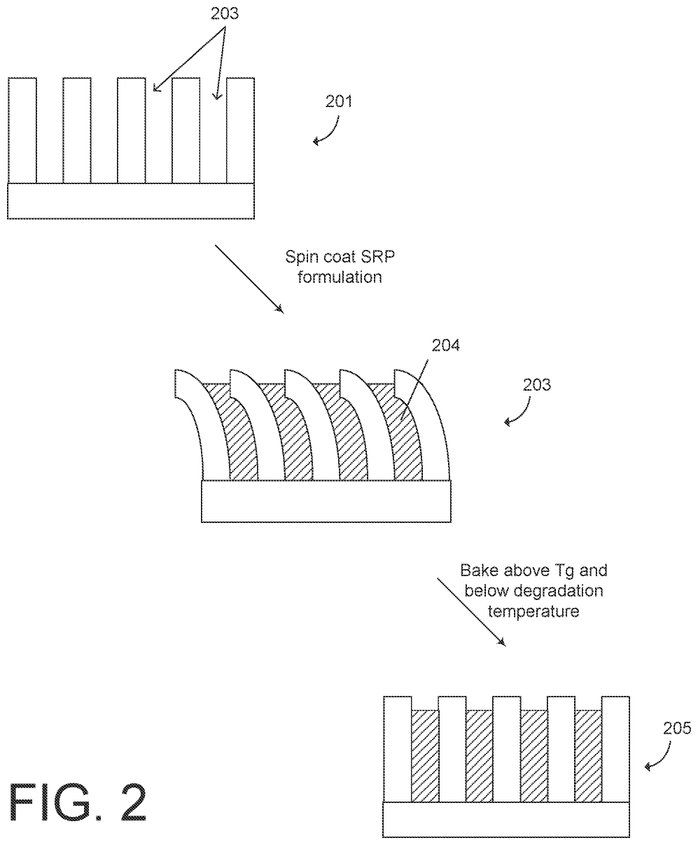

The methods described herein may be advantageous for bracing HAIR structures. After solvent removal, internal stresses in the coated SRP film can result in bending of the HAR structures. This is schematically shown in FIG. 2. Unfilled structure 201 includes high aspect ratio features 203. As described above, an SRP may be deposited in gaps between the high aspect ratio features by spin casting a polymer solution onto the pattern of the HAR structure subsequently spinning the substrate until the solvent evaporates and the polymer is precipitated onto and within the gaps. The spin coating process can generate forces on the HAR structure. There are additional forces generated when the solvent evaporates from the polymer formulation. For amorphous polymers that are below their Tg, these forces can result in structures that are deflected. It can also result in voids within the polymer coating. After spin-coating, the HAR structure is filled with an SRP film 204, but the features are no longer vertical as shown at 205. Baking the coated structure can remove stresses and restore the structural integrity of the HAR structure as shown at 207. It can also remove voids within the film.

Without baking, the features of HAR structure remain bent as depicted at 205. Subsequent removal of the SRP leaves behind bent or collapsed features, which are unsuitable for integration into semiconductor devices. As depicted in FIG. 2, baking can restore the structure.

For HAR bracing and surface protection applications, baking can remove voids in the film. If left in the films, the voids can reduce the effectiveness of the SRP film in bracing an HAR structure or protecting a surface.

However, baking should be done sufficiently below the SRP degradation temperature to avoid SRP degradation. If the SRP degrades during the bake operation, a HAR structure will remain bent and/or uncontrolled removal of the SRP can result to collapse of the features. Premature degradation of a blanket surface protection film can leave the underlying surface less protected or unprotected.

For some SRPs, the degradation temperature is above or close to the Tg or Tm of the SRP. As discussed further below, an SRP formulation may include a plasticizer to depress the Tg or Tm to a temperature sufficiently below the degradation temperature that a bake can be carried out without any degradation of the SRP.

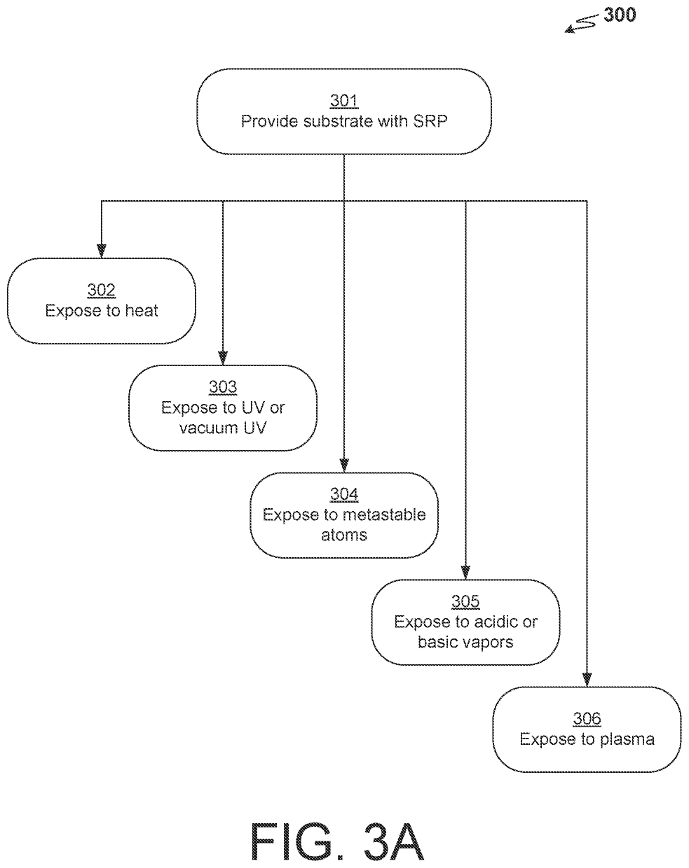

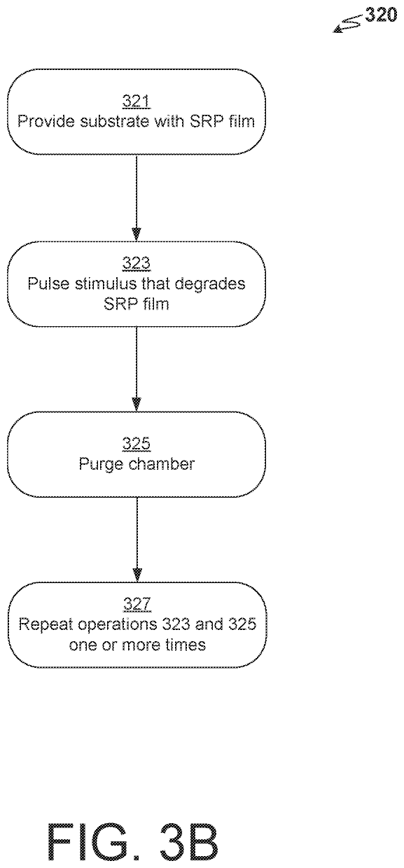

After filling a structure with an SRP formulation as in FIG. 2, a controlled exposure to a stimulus is used to remove the SRP slowly to prevent collapse of the structure. FIGS. 3A and 3B shows process flow diagrams showing examples of methods of controlled exposure to a stimulus to degrade the SRP. The methods may also be used to remove blanket surface protection films.

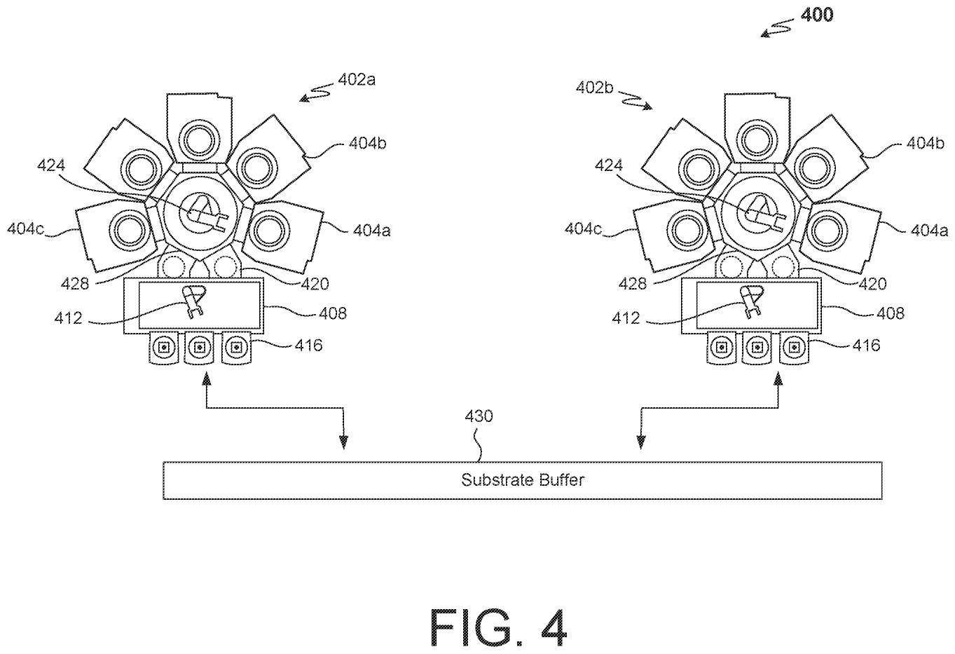

Referring to FIG. 3A, a substrate is provided with SRP film in an operation 301. Operations 302-306 provide exposure to various types of stimuli, in which operations 302-306 may be used alone or in combination. Examples of apparatus that the substrate may be provided to are described below with reference to FIG. 4. In some embodiments, operation 301 involves providing the substrate to a processing chamber. In other embodiments, the substrate is in the chamber from a previous processing operation. The SRP film may be provided in a variety of forms—for example, in a gap between features of a structure or as blanket film on all or part of a substrate. As indicated above, the SRP has undergone a thermal anneal (also referred to as a bake operation). In some embodiments, the SRP is provided after a substantial queue time.

Within the chamber, the substrate can be exposed to heat in an operation 302. Heat can be provided as a constant temperature hold. Alternatively, heat can be provided as a ramped temperature, in which increasing or decreasing temperature ramping can be used between temperature holds. Such thermal energy can provide sufficient energy to depolymerize the SRP by providing heat at a temperature that is above the Tc. Such conditions can include exposure to a temperature of up to 400° C. for an SRP having a Tc that is below 400° C., in which the SRP is kinetically trapped below the Tc. In other embodiments, thermal exposure can include a temperature from about 50° C. to about 800° C. (e.g., about 50° C. to 150° C., 50° C. to 300° C., 50° C. to 500° C., 150° C. to 300° C., 150° C. to 400° C., 150° C. to 500° C., 200° C. to 400° C., 200° C. to 500° C., 200° C. to 600° C., 250° C. to 500° C., 250° C. to 600° C., 300° C. to 500° C., 300° C. to 550° C., 300° C. to 600° C., etc.). In particular embodiments, thermal exposure includes from about 300° C. to about 500° C. (e.g., for removing films including pure SRP). In other embodiments, thermal exposure includes exposure to an elevated temperature (e.g., up to 800° C.) with a fast ramp rate and a shorter time. When additives (e.g., a photoacid generator (PAG) or any herein) are used, the temperature for removal can be between about 50° C. and about 125° C., in addition to exposure to other stimulus that can beneficially activate the additive (e.g., UV exposure to activate the PAG).

For basic thermal removal of surface protection films (e.g., providing a substrate on a hot plate), exposure time can be from about 20 seconds to about 400 seconds (e.g., about 30 to 300 seconds). Thicker films can use longer exposure to heat for SRP removal, as compared to thinner films. Film thickness required will be application dependent. For instance, some removal thermal processes (e.g., using a rapid thermal processor (RTP)) can include higher temperatures (e.g., more than about 400° C.) for very short times (e.g., one to two seconds of exposure for RTP, as well as millisecond exposure times for flash lamp type processes). For applications that are thermal budget sensitive, RTP-type conditions can be employed, whereas other processes may employ a hot plate under vacuum.

Alternatively, the SRP can be removed by exposure to radiation (e.g., JV radiation or IR radiation), either with or without vacuum, in an operation 303. In some instances, process conditions include exposure to about 400° C. under vacuum at about 2.5 W/cm² UV dose rate. In other instances, process conditions (e.g., for an SRP employed with a photoacid generator) includes exposure to about 110° C. under vacuum for at about 0.05 mW/cm² UV dose rate. In any of these process conditions, exposure can include from about 100 seconds to about 400 seconds (e.g., about 300 seconds).

For radiation removal of surface protection films (e.g., pure SRP), exposure time can be from about 20 seconds to about 400 seconds (e.g., about 30 to 300 seconds). Thicker films can use longer exposure to radiation (e.g., UV) for SRP removal, as compared to thinner films. Film thickness required will be application dependent. For films with acid generating additives (e.g., PAG), the exposure times may range from two minutes to ten minutes. Exposure time can depend on many conditions, including the loading of the additives, wafer temperature, UV dose rate, and film thickness. These requirements, in turn, will be application dependent (e.g., depend on feature dimensions, aspect ratio, pattern density, etc.).

Radiation dosage can be, e.g., from about 0.1 mW/cm² to about 15 W/cm² for UV. For bracing applications in which rate control of the degradation can be desired, lower dose rates can be employed, e.g., from about 0.01 to about 0.07 mW/cm². For pure SRP film removal from blanket surfaces, higher dose rates can be employed, e.g., about 2.5 W/cm². Generally, the higher the dose rate, the cleaner the removal. Of course, radiation exposure can also be application dependent, and excessive radiation can be avoided to mitigate substrate damage.

During radiation exposure, the substrate can be maintained at an elevated temperature (e.g., from about 300° C. to about 500° C., including about 400° C.). When the formulation includes acid generating additives (e.g., PAG), then lower temperatures can be combined with UV exposure to provide a controlled degradation rate (e.g., temperature range of about 50° C. to about 125° C. or from about 100° C. to about 110° C.).

Metastable atoms are employed in another operation 304. The metastable atoms can be generated from a noble gas plasma, the noble gas being one or more of helium (He), neon (Ne), argon (Ar), krypton (Kr), and xenon (Xe), to remove residue from the substrate. In some embodiments, the metastable species are not chemically reactive and do not appreciably affect the underlying surface. The metastable species from the noble gas plasma can be effective at removing residues that remain after exposure to other stimuli such as heat.

In the methods described herein, removing SRPs includes exposure to high energy metastable species, generated in a noble gas plasma, at an elevated temperature. The metastable species have sufficient energies and lifetimes to scission bonds on the polymer or other residues. At temperatures greater than the ceiling temperature, there is a strong thermodynamic driving force to revert to volatile monomers once bond scissioning has occurred. The metastable species are not chemically reactive and do not appreciably affect the underlying surface. The metastable species are effective at removing residue that remains after exposure to other stimuli such as heat. This residue may be some SRP that remains polymerized or cross-linked and/or carbonized shards that is detectable by ellipsometry. While most of the SRP can be removed by the stimuli described above, this residue can be difficult to fully remove by those methods. Without being bound by a particular theory, the metastables may remove residues by re-initiating chain scissioning that may have stopped prematurely due to side product formation, by breaking down char that may have formed during the depolymerization process, and by aiding monomer desorption.

In some embodiments, most of the SRP is removed before exposing the substrate to the metastable atoms. In some embodiments, the substrate is exposed to the metastable atoms before most of the SRP is removed. In some embodiments, the plasma pressure is between about 10 mTorr to 10 Torr. In some embodiments, the plasma pressure is between about 100 mTorr and 1 Torr. In some embodiments, the SRP is provided between HAR structures. In some embodiments, the SRP is provided as a protective coating on substrate. In some embodiments, the plasma is generated in an inductively coupled plasma (ICP) source. In some such embodiments, the ICP source is separated from the substrate by a showerhead or other filter. In some embodiments, the plasma is generated in capacitively coupled plasma (CCP) source. Any other type of plasma source may be used. In some embodiments, exposing the substrate to a stimulus and exposing the substrate to the metastable atoms are performed in the same chamber.

Processing and plasma source chamber pressure may be used to control the plasma-based removal. Pressure is important to control the density of the metastable atoms. If pressure is too low, the density of metastable atoms may not be high enough to efficiently clean the surface. If the pressure is too high, metastable species may be lost to collisions. Example pressures may range from 10 mTorr to 10 Torr, 100 mTorr to 1 Torr, 100 mTorr to 700 mTorr, 200 mTorr to 1 Torr, or 200 mTorr to 2 Torr.

Substrate temperature and plasma power may also be used to control removal. Temperature is high enough such that it is above the ceiling temperature of the polymer. Higher temperatures aid removal with the maximum temperature limited by the thermal budget of the device or other materials on the substrate. Example temperatures may range from 150° C. to 1000° C. or from 150° C. to 400° C. Plasma power is high enough to generate metastable atoms. Example powers may range from 500 W to 5000 W or from 800 W to 5000 W, e.g., 2500 W for a 300 mm wafer, and scale linearly with substrate area. Example exposure times may range from 10 seconds to 300 seconds or from 10 seconds to 180 seconds.

As seen in FIG. 3A, yet other conditions include exposure to acidic or basic vapors in an operation 305 or exposure to plasma in an operation 306. Such vapors can be provided by a reactant, such as an acid (e.g., having a pKa of less than 7, and in some embodiments less than 4, or less than 2) or a base (e.g., having a pKb of less than 7, and in some embodiments, less than 4 or less than 2). Non-limiting reactants include sulfurous acid, nitric acid, carbonic acid, or ammonium hydroxide.

A catalyst can be used with the acid, base, or a reactant that forms the acid or base. Non-limiting catalysts include hydrogen bromide (HBr), hydrogen chloride (HCl), hydrogen fluoride (HF), hydrogen iodide (HI), nitric acid (HNO₃), formic acid (CH₂O₂), acetic acid (CH₃COOH), formonitrile (HCN), sulfurous acid (H₂SO₃), carbonic acid (H₂CO₃), nitrous acid (HNO₂), or ammonia (NH₃), and methyl or ethyl amine gas or vapor may be used. In some examples, when HBr vapor is used, the substrate is maintained at a pressure in a range from 1 mTorr to 5000 mTorr (e.g., from 5 mTorr to 5000 mTorr) and a temperature in a range from 0° C. to 200° C. (e.g., from 0° C. to 100° C.). In some examples, the substrate is maintained at a pressure in a range from 750 mTorr to 1500 mTorr and a temperature in a range from 35° C. to 70° C. In some examples, the temperature of the substrate is maintained at a pressure of 1000 mTorr and a temperature of 60° C. The amount of acidic vapor or vapor of other compound is controlled to limit the diffusion. Exposure time can depend on the strength of the acid or base, as well as film thickness and exposure temperature (e.g., from about 20° C. to about 125° C. or from about 100° C. to about 125° C.). Non-limiting exposure time can include less than about 60 seconds or on the order of minutes.

Removal can occur in a single step or in a plurality of steps. As seen in FIG. 3B, a method 320 can include providing a substrate with an SRP film in an operation 321. Then, a stimulus that degrades SRP is pulsed in the chamber in an operation 323. Such stimulus can include exposure to a compound (e.g., an acid, a base, a compound that forms an acid or base, plasma, metastable compounds, etc.) or a reaction condition (e.g., UV radiation, IR radiation, heat, etc.). In some embodiments, removal includes exposure to heat and/or radiation, thus eliminating the need for plasma and/or harsh wet chemistries that will modify the sensitive surfaces that need to be protected.

When a compound is used, the partial pressure of the vapor and/or the pulse time can be controlled to control the overall exposure to the vapor and the diffusion depth. The chamber can be purged in an operation 325. Purging can involve evacuating the chamber and/or flowing inert gas to be swept out through the chamber. Such a gas may be, for example, continuously flowing including during operation 323 or may be itself pulsed into the chamber. During operation 325, volatilized monomer or SRP fragment may be pumped or purged out of the chamber. Operations 323 and 325 are repeated until the SRP is removed in an operation 327. As indicated above, in some embodiments, the SRP is exposed to reactants sequentially in each cycle. This can provide additional control over the process and may be implemented in various ways.

In other embodiments, removal can include exposure to two reactants that react to form an acid or base that can trigger the degradation of the SRP. The exposure occurs sequentially to provide more precise top down control. In some embodiments, the methods involve diffusing a compound, or a reactant that reacts to form a compound, only to a top portion of the SRP. The top portion is then degraded and removed, leaving the remaining SRP intact. The exposure and removal cycles can be repeated. Optionally, a purge operation can follow the exposure operation to remove the compound or reactant from the chamber.

Non-limiting reactants (e.g., to form an acid or base) can include water vapor with one of ammonia (NH₃) or a gaseous oxide, which reacts with the water vapor to an acidic or basic species. For instance, NH₃ and water can react to form ammonium hydroxide (NH₄OH). Examples of gaseous oxides include nitrogen dioxide (NO₂, which can react with water to form nitric acid, HNO₃), sulfur dioxide (SO₂, which can react with water to form sulfurous acid, H₂SO₃), and carbon dioxide (CO₂, which can react with water to form carbonic acid, H₂CO₃). Other oxides may react with water or another reactant to form acids or bases.

According to various embodiments, the reaction may be catalyzed or uncatalyzed. In some embodiments, a catalyst (e.g., a thermally activated catalyst) may be provided in the SRP, delivered with a reactant, or introduced as a separate pulse. However, in many embodiments, the reaction is uncatalyzed such that SRP is provided free of catalysts. This can facilitate SRP removal. In some embodiments, the reaction is byproduct-free.

### SRPs

The SRPs as described herein are polymers that are in thermal equilibrium with their constituent monomers at a ceiling temperature (Tc). On exposure to an appropriate stimulus, an SRP is de-polymerized with the monomer products easily removed from the surface of the substrate. The ceiling temperature is an intrinsic property of the polymer. According to various embodiments, the SRPs have ceiling temperatures between −80° C. and 400° C.

In many embodiments, the SRPs are low ceiling temperature (Tc) polymers. As used herein, the term low Tc refers to Tc values below a removal temperature. In some embodiments, the Tc is below room temperature, such that the polymers are thermodynamically unstable at room temperature. Instead, the low Tc polymer is kinetically trapped to allow prolonged storage at room temperature. In some examples, the stable storage period is on the order of months or years. Low Tc polymers will rapidly de-polymerize to its monomer constituents if an end-group or main chain bond is broken. Thus, the polymer de-polymerizes in response to stimuli such as ultraviolet (UV) light, heat, thermal catalyst, photocatalyst, noble gas plasma, or an acidic/basic catalyst. The monomer products are volatile and leave or can be easily removed from the surface and chamber.

While in some embodiments, the Tc is below room temperature, in the context of semiconductor processing, low Tc may also refer to ceiling temperatures that are higher than room temperature. For example, removal temperatures of up to 400° C. may be used, meaning that the ceiling temperature is below 400° C. In some embodiments, the SRP is characterized by having a Tc below 200° C. In some embodiments, the SRP is characterized by having a Tc between −80° C. and 200° C., between −80° C. and 150° C., or between −30° C. and 100° C. In some embodiments, having a ceiling temperature of no more than about 10° C. is advantageous such that de-polymerization into constituent monomers can occur without burning or charring the SRP.

For low-Tc polymer systems, the glass transition often occurs at a higher temperature than the degradation temperature. As discussed further below, adding plasticizer can depress the Tg below the degradation temperature of the amorphous polymer system.

Example of SRPs are provided below. However, the methods described herein may be used with any SRPs. In some embodiments, the SRPs are co-polymers or homopolymers including poly(aldehydes). Non-limiting examples of homopolymer or constituent polymers of a copolymer in SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a polyglyoxylamide, a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

In some embodiments, the SRP is a homopolymer. Such a polymer can have any useful number n of monomers, such as n is from about 2 to about 100,000 (e.g., about 2 to 50, 2 to 100, 2 to 200, 2 to 300, 2 to 400, 2 to 500, 2 to 1,000, 2 to 2,000, 2 to 5,000, 2 to 10,000, 2 to 20,000, 2 to 50,000, 2 to 100,000, 3 to 50, 3 to 100, 3 to 200, 3 to 300, 3 to 400, 3 to 500, 3 to 1,000, 3 to 2,000, 3 to 5,000, 3 to 10,000, 3 to 20,000, 3 to 50,000, 3 to 100,000, 4 to 50, 4 to 100, 4 to 200, 4 to 300, 4 to 400, 4 to 500, 4 to 1,000, 4 to 2,000, 4 to 5,000, 4 to 10,000, 4 to 20,000, 4 to 50,000, 4 to 100,000, 5 to 50, 5 to 100, 5 to 200, 5 to 300, 5 to 400, 5 to 500, 5 to 1,000, 5 to 2,000, 5 to 5,000, 5 to 10,000, 5 to 20,000, 5 to 50,000, 5 to 100,000, 10 to 50, 10 to 100, 10 to 200, 10 to 300, 10 to 400, 10 to 500, 10 to 1,000, 10 to 2,000, 10 to 5,000, 10 to 10,000, 10 to 20,000, 10 to 50,000, 10 to 100,000, 50 to 100, 50 to 200, 50 to 300, 50 to 400, 50 to 500, 50 to 1,000, 50 to 2,000, 50 to 5,000, 50 to 10,000, 50 to 20,000, 50 to 50,000, 50 to 100,000, 100 to 200, 100 to 300, 100 to 400, 100 to 500, 100 to 1,000, 100 to 2,000, 100 to 5,000, 10 to 10,000, 100 to 20,000, 100 to 50,000, and 100 to 100,000). In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives.

Example of SRPs are provided below. However, the methods described herein may be used with any SRPs. In some embodiments, the SRPs are homopolymers including poly(aldehydes). SRPs can be any appropriate homopolymer in linear or cyclic form. Non-limiting SRPs include a poly(phthalaldehyde), a poly(aldehyde), a poly(benzyl carbamate), a poly(benzyl ether), a poly(alpha-methyl styrene), a poly(carbonate), a poly(norbornene), a poly(olefin sulfone), a poly(glyoxylate), a poly(glyoxylamide), a poly(ester), or a poly(methyl methacrylate), as well as derivatives thereof. Such derivatives can include replacement of oxy (—O—) with an optionally substituted heteroalkylene, as defined herein, as well as substitutions with one or more substitution groups, as described herein for alkyl.

Yet other SRPs can include those having a structure of one of formulas (I)-(XV), (Ia), (Ib), or (Ic). Such SRPs can be a linear polymer or a cyclic polymer. If linear, the polymer can include any useful end groups that terminate the molecule. Such end groups can depend on the reactive end groups present on the monomers employed to synthesize the polymer. In particular embodiments, end groups can include those fragments formed from use of an anionic initiator (e.g., fragments such as alkyl anion, e.g., present in n-BuLi, s-BuLi, etc.), from use of an acylation or alkylation reagent (e.g., fragments such as acyl or optionally substituted alkanoyl, such as formyl, acetyl, benzoyl, methyl, ethyl, etc.), from use of a conjugated alkylene monomer (e.g., such as a quinone methide monomer), or from use of an alcohol termination agent (e.g., fragments such as optionally substituted alkoxy). The end groups can include any useful binding group or a reactive group (e.g., those including optionally substituted trialkylsiloxy, optionally substituted alkenyl, optionally substituted aryl, etc.).

The SRP can include a poly(phthalaldehyde) or a derivative thereof, which can be a homopolymer that is linear or cyclic. In one embodiment, the SRP is or includes a structure of formula (I):

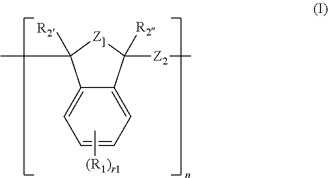

or a salt thereof, wherein
each R₁, is, independently, H, optionally substituted alkyl, optionally substituted alkoxy, optionally substituted alkenyl, optionally substituted aryl, or halo;
each of R_{2′} and R_{2″} is, independently, H, optionally substituted alkyl, optionally substituted heteroalkyl, or optionally substituted aryl;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (I)), each of R_{2′} and R_{2″} is, independently, H or optionally substituted alkyl. In some embodiments, each of Z₁ and Z₂ is —O—.

The SRP can include a poly(aldehyde) or a derivative thereof, which can be a homopolymer that is linear or cyclic. In one embodiment, the SRP is or includes a structure of formula (II):

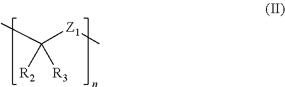

or a salt thereof, wherein:
each of R₂ and R₃ is, independently, H, optionally substituted alkyl, optionally substituted heteroalkyl, or optionally substituted aryl;
Z₁ is —O—, —S—, or optionally substituted heteroalkylene; and
n is from about 2 to about 100,000.

The SRP can include a poly(benzyl carbamate) or a derivative thereof, which can be a homopolymer that is linear or cyclic. In one embodiment, the SRP is or includes a structure of formula (III):

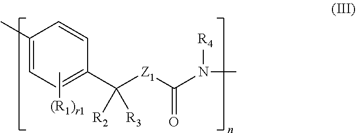

or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
R₄ is H or optionally substituted alkyl;
Z₁ is —O—, —S—, or optionally substituted heteroalkylene;
r1 is an integer from 1 to 4; and
n is from about 2 to about 100,000.

In particular embodiments (e.g., of formula (III)), R₁ is optionally substituted alkoxy. In other embodiments, n is from about 2 to about 100 (e.g., from about 2 to 10, 2 to 15, 2 to 20, 2 to 25, 2 to 30, 2 to 40, 2 to 50, 2 to 75, 4 to 10, 4 to 15, 4 to 20, 4 to 25, 4 to 30, 4 to 40, 4 to 50, 4 to 75, and 4 to 100).

The SRP can include a poly(benzyl ether) or a derivative thereof, which can be a homopolymer that is linear or cyclic. In one embodiment, the SRP is or includes a structure of formula (IV):

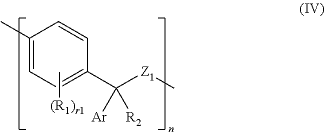

or a salt thereof, wherein:
each R₁ is, independently, H, optionally substituted alkyl, optionally substituted alkoxy, optionally substituted alkenyl, optionally substituted aryl, or halo;
R₂ is H, optionally substituted alkyl, optionally substituted heteroalkyl, or optionally substituted aryl;
Ar is optionally substituted aryl, optionally substituted alkyl, or optionally substituted aralkyl;
Z₁ is —O—, —S—, or optionally substituted heteroalkylene;
r1 is an integer from 1 to 4; and
n is from about 2 to about 100,000.

In particular embodiments (e.g., of formula (IV)), R₁ is optionally substituted alkyl. In other embodiment, Ar is optionally substituted phenyl. In other embodiments, n is from about 2 to about 5000.

The SRP can include a poly(benzyl dicarbamate) or a derivative thereof, which can be a homopolymer that is linear or cyclic. In one embodiment, the SRP is or includes a structure of formula (V):

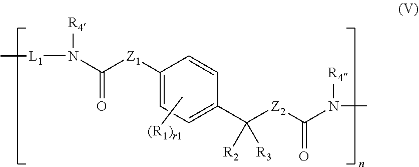

S or a salt thereof, wherein:
each R₁ is, independently, H, optionally substituted alkyl, optionally substituted alkoxy, optionally substituted alkenyl, optionally substituted aryl, or halo;
each of R₂ and R₃ is, independently, H, optionally substituted alkyl, optionally substituted heteroalkyl, or optionally substituted aryl;
each of R_{4′}, and R_{4″} is, independently, H or optionally substituted alkyl;
L₁ is optionally substituted alkylene, optionally substituted heteroalkylene, optionally substituted arylene, or optionally substituted cycloalkylene;
each of Z₁ and Z₂ is, independently, —O—, —S—, or optionally substituted heteroalkylene;
r1 is an integer from 1 to 4; and
n is from about 2 to about 100,000.

In particular embodiments (e.g., of formula (V)), R₁ is optionally substituted alkyl. In other embodiment, Ar is optionally substituted phenyl. In other embodiments, n is from about 2 to about 5000. In other embodiments (e.g., of formula (V)), each of R_{4′} and R_{4″} is, independently, optionally substituted alkyl. In some embodiments, L₁ is optionally substituted alkylene. In other embodiments, Z₁ and Z₂ is —O—.

The SRP can include a poly(dicarbamate) or a derivative thereof, which can be a homopolymer that is linear or cyclic. In one embodiment, the SRP is or includes a structure of formula (VI):

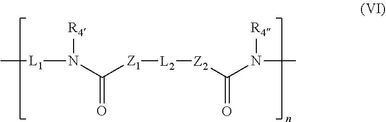

or a salt thereof, wherein:
each of R_{4′}, and R_{4″} is, independently, H or optionally substituted alkyl;
each of L₁ and L₂ is, independently, optionally substituted alkylene, optionally substituted heteroalkylene, optionally substituted arylene, or optionally substituted cycloalkylene, in which L₂ can optionally be a covalent bond;
each of Z₁ and Z₂ is, independently, —O—, —S—, or optionally substituted heteroalkylene; and
n is from about 2 to about 100,000.

In particular embodiments (e.g., of formula (VI)), each of R_{4′} and R_{4″} is, independently, optionally substituted alkyl. In some embodiments, each of L₂ and L₂ is, independently, optionally substituted alkylene. In other embodiments, each of Z₁ and Z₂ is, independently, —O— or —S—.

The SRP can include a poly(alpha-methyl styrene) or a derivative thereof, which can be a homopolymer that is linear or cyclic. In one embodiment, the SRP is or includes a structure of formula (VII):

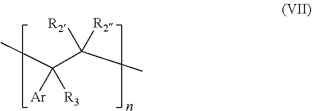

or a salt thereof, wherein:
each of R_{2′}, R_{2″}, and R₃ is, independently, H, optionally substituted alkyl, optionally substituted heteroalkyl, or optionally substituted aryl;
Ar is optionally substituted aryl, optionally substituted alkyl, or optionally substituted aralkyl; and
n is from about 2 to about 100,000.

The SRP can include a poly(carbonate) or a derivative thereof, which can be a homopolymer that is linear or cyclic. In one embodiment, the SRP is or includes a structure of formula (VIII):

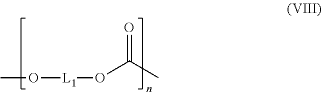

or a salt thereof, wherein:
L₁ is optionally substituted alkylene, optionally substituted heteroalkylene, optionally substituted arylene, or optionally substituted cycloalkylene; and
n is from about 2 to about 100,000.

In particular embodiments (e.g., of formula (VIII)), L₁ is optionally substituted alkylene, optionally substituted heteroalkylene, or optionally substituted cycloalkylene. In some embodiments, the optionally substituted heteroalkylene is —X-Ak-X—, in which X is oxy and Ak is optionally substituted alkylene. Non-limiting SRPs can include poly(ethylene carbonate), poly(propylene carbonate) (PPC), poly(butylene carbonate) (PBC), poly(cyclohexene carbonate) (PCHC), poly(norbornene carbonate) (PNC), and poly(cyclohexene propylene carbonate) (PCPC).

The SRP can include a poly(norbornene) or a derivative thereof, which can be a homopolymer that is linear or cyclic. In one embodiment, the SRP is or includes a structure of formula (IX):

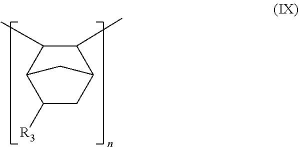

or a salt thereof, wherein:
R₃ is H, optionally substituted alkyl, optionally substituted heteroalkyl, or optionally substituted aryl; and
n is from about 2 to about 100,000.

The SRP can include a poly(olefin sulfone) or a derivative thereof, which can be a homopolymer that is linear or cyclic. In one embodiment, the SRP is or includes a structure of formula (X):

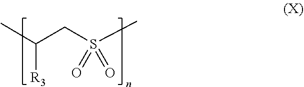

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (X)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)^{d1}R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

The SRP can include a poly(glyoxylate) or a derivative thereof, which can be a homopolymer that is linear or cyclic. In one embodiment, the SRP is or includes a structure of formula (XI):

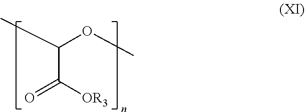

or a salt thereof, wherein:
R₃ is H, optionally substituted alkyl, optionally substituted heteroalkyl, or optionally substituted aryl; and
n is from about 2 to about 100,000.

In particular embodiments (e.g., of formula (XI)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl.

The SRP can include a poly(methyl methacrylate) or a derivative thereof, which can be a homopolymer that is linear or cyclic. In one embodiment, the SRP is or includes a structure of formula (XII):

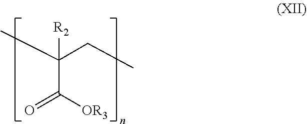

or a salt thereof, wherein:
each of R₂ and R₃ is, independently, H, optionally substituted alkyl, optionally substituted heteroalkyl, or optionally substituted aryl; and
n is from about 2 to about 100,000.

In particular embodiments (e.g., of formula (XII)), R is optionally substituted alkyl. In other embodiments (e.g., of formula (XII)), R₃ is optionally substituted alkyl or optionally substituted heteroalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl.

The SRP can include a poly(glyoxylamide) or a derivative thereof, which can be a homopolymer that is linear or cyclic. In one embodiment, the SRP is or includes a structure of formula (XIII):

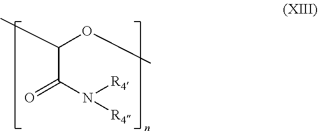

or a salt thereof, wherein:
each of R_{4′} and R_{4″} is, independently, H, optionally substituted alkyl, optionally substituted aminoalkyl, optionally substituted heteroalkyl, or R_{4′}, and R_{4″}, taken together with the nitrogen atom to which each are attached, form a heterocyclyl group, as defined herein; and
n is from about 2 to about 100,000.

In particular embodiments (e.g., of formula (XIII)), each of R^{4′} and/or R^{4″} is optionally substituted alkyl, optionally substituted heteroalkyl, or optionally substituted aminoalkyl, such as, e.g., -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl. In other embodiments, R_{4′} is H or alkyl, and R_{4″} is optionally substituted alkyl, optionally substituted heteroalkyl, or optionally substituted aminoalkyl (e.g., as described above). In yet other embodiment, R_{4′}, and R_{4″}, taken together with the nitrogen atom to which each are attached, form a heterocyclyl group, as defined herein. Non-limiting heterocyclyl groups include pyrrolidinyl, piperidinyl, morpholinyl, oxazolyl, isoxazolyl, pyrrolyl, pyrazolyl, and the like.

As can be seen in formula (I) and (II), the SRP can be a poly(aldehyde), including poly(phthalaldehyde) or a generic poly(aldehyde) with a backbone consisting of alternating carbon and oxygen, including poly(oxymethylene). Such SRPs can be a linear or a cyclic homopolymer. The SRP can be a poly(phthalaldehyde) or a derivative thereof, such as a polymer including a structure of formula (Ia):

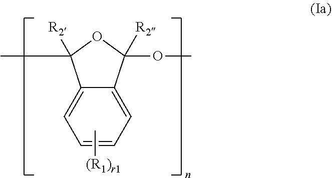

or a salt thereof, for any R₁, R_{2′}, R_{2″}, r1, and n described herein. In some instances, n is an integer from 4 to 100,000.

In other embodiments, the poly(phthalaldehyde) is cyclic. In some instances, the polymer has structure of formula (Ib) or (Ic):

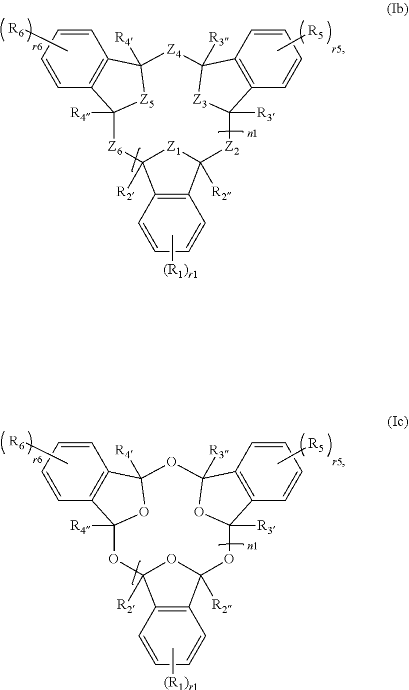

or a salt thereof, or any R₁, R₅, R₆, R_{2′}, R_{2″}, R_{3′}, R_{3″}, R_{4′}, R_{4″}, Z₁, Z₂, Z₃, Z₄, Z₅, Z₆, r1, r5, r6, and n1 described herein. In some instances, n1 is an integer from 1 to 100.

In any embodiment herein (e.g., in formula (I)-(VI) and (Ib)), each of Z₁ to Z₆, L₁, and L₂, if present, is, independently, an optionally substituted heteroalkylene selected from —CR₂R₃O—, —OCR₂R₃—, —OCR₂R₃O—, —(CR₂R₃S)ₕ₁CR₂R₃—, —S(CR₂R₃S)ₕ₁—, —CR₂R₃S—, —SCR₂R₃—, —SCR₂R₃S—, —(CR₂R₃S)ₕ₁CR₂R₃—, and —S(CR₂R₃S)ₕ₁—, in which each of R₂ and R₃ is, independently, H, optionally substituted alkyl, or optionally substituted aryl, and h₁ is an integer from 1 to 5. In other embodiments, each of Z₁ to Z₆, L₁, and L₂, if present, is, independently, —O— or an optionally substituted heteroalkylene.

In any embodiment herein (e.g., in formula (I)-(V), (VII), and (XII)), each of R₂, R_{2′}, and R_{2″}, if present, is, independently, H or optionally substituted alkyl (e.g., C₁₋₆ alkyl).

In any embodiment herein (e.g., in formula (II), (III), (V), (VII), (IX), (X), (XI), and (XII)), R₃ is optionally substituted aryl.

In any embodiment herein (e.g., in formula (II), (III), (V), (VII), (IX), (X), (XI), and (XII)), R₃ is optionally substituted heteroalkyl, such as, e.g., —OC(O)—R^{O1}, —NR^{N1}—C(O)—R^{O1}, —OC(O)NR^{N1}R^{N2}, -(Ak-O)ₕ₁R^{O1} or -Ak-NR^{N1}R^{N2}, in which Ak is optionally substituted alkylene, h1 is from 1 to 5, and each of R^{O1}, R^{N1}, and R^{N2} is, independently, H or optionally substituted alkyl (e.g., hydroxyalkyl, carboxyalkyl, aminoalkyl, or azidoalkyl).

In any embodiment herein, the polymer is a homopolymer. Such a polymer can have any useful number n of monomers, such as n is from about 2 to about 100,000 (e.g., about 2 to 50, 2 to 100, 2 to 200, 2 to 300, 2 to 400, 2 to 500, 2 to 1,000, 2 to 2,000, 2 to 5,000, 2 to 10,000, 2 to 20,000, 2 to 50,000, 2 to 100,000, 3 to 50, 3 to 100, 3 to 200, 3 to 300, 3 to 400, 3 to 500, 3 to 1,000, 3 to 2,000, 3 to 5,000, 3 to 10,000, 3 to 20,000, 3 to 50,000, 3 to 100,000, 4 to 50, 4 to 100, 4 to 200, 4 to 300, 4 to 400, 4 to 500, 4 to 1,000, 4 to 2,000, 4 to 5,000, 4 to 10,000, 4 to 20,000, 4 to 50,000, 4 to 100,000, 5 to 50, 5 to 100, 5 to 200, 5 to 300, 5 to 400, 5 to 500, 5 to 1,000, 5 to 2,000, 5 to 5,000, 5 to 10,000, 5 to 20,000, 5 to 50,000, 5 to 100,000, 10 to 50, 10 to 100, 10 to 200, 10 to 300, 10 to 400, 10 to 500, 10 to 1,000, 10 to 2,000, 10 to 5,000, 10 to 10,000, 10 to 20,000, 10 to 50,000, 10 to 100,000, 50 to 100, 50 to 200, 50 to 300, 50 to 400, 50 to 500, 50 to 1,000, 50 to 2,000, 50 to 5,000, 50 to 10,000, 50 to 20,000, 50 to 50,000, 50 to 100,000, 100 to 200, 100 to 300, 100 to 400, 100 to 500, 100 to 1,000, 100 to 2,000, 100 to 5,000, 10 to 10,000, 100 to 20,000, 100 to 50,000, and 100 to 100,000). In other embodiments, the polymer is cyclic, in which n is from about 3 to about 100. In other embodiments, the cyclic polymer includes any useful number n1+2 of monomers, such as n1 from about 1 to about 100.

In particular embodiments, the SRPs may also be any appropriate linear or cyclic copolymer including the pure phthalaldehyde homopolymer, a homopolymer of poly(phthalaldehyde) derivatives such as poly(4,5-dichlorophthalaldehyde), or a homopolymer of poly(aldehyde) derivatives. SRPs can include a copolymer including a structure of one of formulas (I)-(XIII), (Ia), (Ib), (Ic), or a salt thereof, as well as any copolymer described herein (e.g., one of formulas (XIV) or (XV)).

Further example of SRPs are provided below. In some embodiments, the SRPs are copolymers including poly(aldehydes). In particular embodiments, they may be self-immolative polymers as described in U.S. Patent Publication No. 2018/0155483, which was published on Jun. 7, 2018 and which is hereby incorporated herein by reference in its entirety. Examples of copolymers in that reference include those of Formula (XIV):

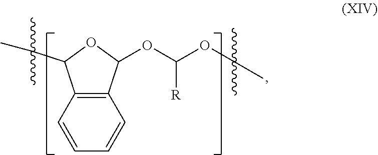

wherein:

R is substituted or unsubstituted C₁₋₂₀ alkyl, C₃₋₂₀ alkoxy, C₂₋₂₀ alkenyl, C₂₋₂₀ alkynyl, C₆₋₁₀ heteroaryl, C₃₋₁₀ cycloalkyl, C₃₋₃₀ cycloalkenyl, C₃₋₁₀ heterocycloalkyl, or C₃₋₁₀ heterocycloalkenyl; and, when substituted, R is substituted with C₁₋₂₀ alkyl, C₁₋₂₀ alkoxy, C₂₋₂₀ alkenyl, C₂₋₂₀ alkynyl, C₆₋₁₀ aryl, C₆₋₁₀ heteroaryl, carboxyaldehyde, amino, sulfonic acid, sulfinic acid, fluoroacid, phosphonic acid, ether, halo, hydroxyl, ketone, nitro, cyano, azido, silyl, sulfonyl, sulfinyl, or thiol.

In particular embodiments, the SRPs are cyclic copolymers of the phthalaldehyde monomer with a second aldehyde such as ethanal, propanal, or butanal. Examples of such copolymers are given in U.S. Patent Publication No. 2018/0155483 as Formula (XV):

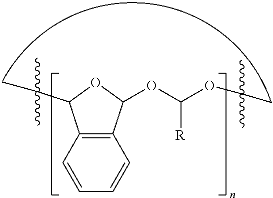

(XV), wherein n is an integer from 1 to 100,000 and R can be any described herein (e.g., such as for Formula (XIV)).

Specific examples in U.S. Patent Publication No. 2018/0155483 include copolymers of phthalaldehyde and one or more of acetaldehyde, propanal, butanal, pentanal, hexanal, heptanal, octanal, nonanal, decanal, undecanal, propenal, butenal, pentenal, hexenal, heptenal, octenal, nonenal, decenal, undecenal, and any combination thereof.

The SRPs may also be any appropriate linear or cyclic copolymer including the pure phthalaldehyde homopolymer. It also may be a homopolymer of poly(phthalaldehyde) derivatives such as poly(4,5-dichlorophthalaldehyde).

In other embodiments, the SRP is a homopolymer possessing a low MW, thereby providing a low viscosity polymer for filling gaps.

In any embodiment herein, the SRP can include a monomer that is or has a structure of any of formulas (I)-(XV), (Ia), or a salt thereof, in which n is 1, which is then linked to another monomer by way of a linker. Non-limiting linkers include optionally substituted alkylene, optionally substituted heteroalkylene, optionally substituted (aryl)(alkyl)ene, optionally substituted arylene, optionally substituted cycloalkylene, oxy, or thio. In other embodiments, the linker can be -Ak-, -Ak-X—, —X-Ak-, -(Ak-X)ₕ₁-Ak-, —X-(Ak-X)ₕ₁—, -Ak-Ar—, -Ak-Ar-Ak-, —Ar-Ak-, -(Ak-X)ₕ₁—Ar—, -(Ak-X)ₕ₁—Ar-(Ak-X)ₕ₁—, —Ar-(Ak-X)ₕ₁—, —X-(Ak-X)ₕ₁—Ar—, —X-(Ak-X)ₕ₁—Ar—X-(Ak-X)ₕ₁—, and —Ar—X-(Ak-X)ₕ₁—, in which Ak is an optionally substituted alkylene, Ar is an optionally substituted arylene, X is or includes a non-carbon heteroatom (e.g., —O—, —S—, or —NR^{N1}—, which R^{N1} is H, optionally alkyl, or optionally substituted aryl), and h1 is an integer from 1 to 5.

In any embodiment herein, the SRP can be an amorphous polymer that remains solvent soluble.

The SRP can be synthesized using any corresponding monomer. For instance, the monomer can be or have a structure of any of formulas (I)-(XV), (Ia), or a salt thereof, in which n is 1. The monomer can have any useful end group disposed on either end of such a structure. In other embodiments, the monomer can be volatile and possess a melting point at or below 20° C.

In particular embodiments, the SRP is formed with no unwanted side products. In this way, residue-free vaporization of the polymer can be achieved because side products need not be removed. For removal, scission of one (or few) chemical bonds within the SRP propagates full, rapid depolymerization of the polymer. Since all the bonds are the same (no inadvertent impurities), little or no residue is expected.

The SRP, or a formulation thereof, can be deposited in any useful manner. For instance, the SRP can be spin-coated or vapor deposited. Additional examples of SRPs and methods using SRPs are described in U.S. Pat. Nos. 9,466,511, 9,666,427, 10,008,396, and 10,068,781, each of which are incorporated herein by reference in its entirety.

### SRP Formulations

In some embodiments, SRPs that have degradation temperatures below their glass transition temperatures or melting temperatures may be used. Similarly, an SRP that has a degradation temperature above, but close to, a glass transition temperature or melting temperature may be used. As discussed above, baking SRP above the glass transition temperature and, if applicable, above the melting temperature can relax the stress in the SRP and/or remove voids. However, baking should be done sufficiently below the SRP degradation temperature to avoid SRP degradation. If the SRP degrades during the bake operation, the structure will remain bent and/or uncontrolled removal of the SRP can lead to feature collapse. And if baking is done below the Tg (or for non-amorphous SRPs) below the Tm, the beneficial effects of stress relaxation and/or void removal may not be realized.

For some SRPs, the degradation temperature is above or close to the Tg or Tm of the SRP. As discussed further below, an SRP formulation may include a plasticizer to depress the Tg or Tm to a temperature sufficiently below the degradation temperature that a bake can be carried out without any degradation of the SRP.

To perform the methods described in FIGS. 1A and 1B, the SRP may be formulated with a plasticizer to depress the glass transition temperature or melting temperature. In this manner, the SRP may be heated to reduce internal stresses and/or remove voids without prematurely degrading the SRP.

Examples of plasticizers include phthalate esters such as dimethyl phthalate (DMP), diethyl phthalate (DEP), di-n-butyl phthalate (DBP), diisobutyl phthalate (DIBP), butyl benzyl phthalate (BBP), di-n-hexyl phthalate (DNHP), diisohexyl phthalate (DIHxP), diisononyl phthalate (DINP), diethylhexyl phthalate (DEHP), di(2-propylheptyl) phthalate (DPHP), di-n-octylphthalate (DOP), diisooctyl phthalate (DIOP), diisononyl phthalate, and diisodecyl phthalate (DIDP). In some embodiments, the plasticizer is a C3-C6 ortho-phthalate. Higher molecular weight phthalates may also be used.

In some embodiments, non-phthalate plasticizers may be used. Examples include aliphatic dibasic acid esters including glutarates (e.g., glycol ether glutarate), adipates (e.g., di-(2-ethylhexyl) adipate (DEHA), monomethyl adipate, dimethyl adipate, dioctyl adipate), azelates, and sebacates; benzoate esters (e.g., ethylene glycol) dibenzoate (DEGDB); trimellitates (e.g., trimethyl trimellitate, tri(2-ethylhexyl)trimellitate, tri(octyl,decyl)trimellitate, tri(heptyl,nonyl)trimellitate, and octyltrimellitate); polyesters; citrates; maleates (e.g., dibutyl maleate); glycols; polyethers; and phosphates.

The plasticizer may be provided in relatively small quantity. In some embodiments, it is provided in 1-35 pphr (parts per hundred resin) and may be 10 pphr or lower. As discussed below, a small amount of plasticizer is sufficient to depress the glass transition temperature. Larger quantities of plasticizer can result in phase separation or leave residues after SRP removal. The plasticizer should be soluble in the solvent used to spin coat the SRP solution.

Low ceiling temperature (Tc) polymers may have glass transition temperatures (Tg's) that are close to or above a degradation temperature and benefit from addition of a plasticizer in the formulation. Other SRPs including various polyglyoxylates, polyglyoxylamides, and polysulfones may be annealed without the addition of a plasticizer.

In some embodiments, the SRP is formulated with an organic weak acid. SRP films that include an organic weak acid are stable at room temperature but exhibit accelerated degradation characteristics compared to the neat SRP formulated without the organic weak acid. Organic weak acids are organic acids having a pKa≥1, with examples including tartaric acid and oxalic acid. Examples include linear alkyl carboxylic acids, CₓH2ₓO₂, where X is an integer, and the corresponding dicarboxylic acid variants. Particular examples include including methanoic acid (X=1) and acetic acid (X=2). Particular examples of dicarboxylic acids include ethanedioic acid and propanedioic acid. The organic weak acid may also be variants of any of these with additional alcohol substitutions and/or unsaturated bonds. For example, oxoethanoic acid, 2-hydroxyethanoic acid, prop-2-enoic acid, 2-propynoic acid, 2-hydroxypropanedioic acid, oxopropanedioic acid, 2,2-dihydroxypropanedioic acid, 2-oxopropanoic acid, 2-hydroxypropanoic acid, 3-hydroxypropanoic acid, 2,3-dihydroxypropanoic acid, etc. may be used.

According to various embodiments, an SRP formulation may include a solvent, the SRP, a plasticizer, and, optionally, an organic weak acid. Example solvents include diglyme, tetrahydrofuran, N-methyl-pyrrolidone, dimethylformamide, propylene carbonate, cyclopentanone, anisole, dichlorobenzene, propylene glycol methyl ether acetate, and 2-ethoxyethyl acetate. In some embodiments, the SRP and the organic weak acid may be formulated and stored as separate solutions but mixed together at point of deposition onto the wafer, or at some point relatively shortly beforehand. In some embodiments, the SRP and plasticizer may be provided as a powder to be mixed in the solvent before spin coating.

The formulation, and thus the resultant film, can include a photoacid generator (PAG), in which exposure of the SRP to electromagnetic radiation produces acid. In this way, energetic light (e.g., UV light, IR lights, or x-rays) exposure generates acid to promote in situ degradation of the film. Non-limiting photoacid generators include onium salts, such as iodonium and sulfonium salts having perfluorinated anions (e.g., diaryliodonium and triarylsulfonium salts), bissulfonyldiazomethane compounds, N-sulfonyloxydicarboximide compounds, and O-arylsulfonyloxime compounds. The photoacid generator may optionally include a photosensitizer (e.g., having modified polyaromatic hydrocarbons or fused aromatic rings).

Other acid generators can be used, such as a thermal acid generator that releases acidic moieties upon exposure to heat. In this way, depolymerization of the SRP can include both thermal and acidic processes. Non-limiting examples of thermal acid generators include ammonium salts, sulfonyl esters, and acid amplifiers. And as noted above, in some embodiments, the formulation may include a plasticizer.

According to various embodiments, an SRP may be pre-formulated with the appropriate acid at some point prior to use and then spin-coated onto the substrates for sacrificial bracing or surface protection applications. Alternatively, the SRP may be mixed with the acid at point of use, right before spin-coating. This latter approach may be used to prolong the shelf-life of the SRP in some embodiments, since although it is stable in film form (solid state), it may not be stable in solution once contacted with the acid.

### Apparatus

The processes described above may be implemented in a chamber which may be part of a substrate processing system. The substrate processing system may further include one or more additional substrate processing tools used to process substrates including deposition of SRPs and upstream and downstream processing. Referring now to FIG. 4, a substrate processing system 400 includes one or more substrate processing tools (substrate processing tools 402a and 402b are shown for illustration purposes) and substrate buffer 430 or other substrate storage. Each of the substrate processing tools 402a and 402b includes a plurality of processing chambers 404a, 404b, 404c, etc. (collectively processing chambers 404). For example only, each of the processing chambers 404 may be configured to perform a substrate treatment. In some examples, the substrates may be loaded into one of the processing chambers 404, processed, and then moved to one or more other ones of the processing chambers 404 and/or removed from the substrate processing system 400 (e.g., if all perform the same treatment).

Substrates to be processed are loaded into the substrate processing tools 402a and 402b via ports of a loading station of an atmosphere-to-vacuum (ATV) transfer module 408. In some examples, the ATV transfer module 408 includes an equipment front end module (EFEM). The substrates are then transferred into one or more of the processing chambers 404a-404c. For example, a transfer robot 412 is arranged to transfer substrates from loading stations 416 to load locks 420. A vacuum transfer robot 424 of a vacuum transfer module 428 is arranged to transfer substrates from the load locks 420 to the various processing chambers 404.

After processing in one or more of the substrate processing tools 402a and 402b, the substrates may be transported outside of a vacuum environment. For example, the substrates may be moved to a location for storage (such as the substrate buffer 430). In other examples, the substrates may be moved directly from the substrate processing tool to another substrate processing tool for further processing or from the substrate buffer 430 to another substrate processing tool for further processing.

Exposure of the substrate to ambient conditions may cause defects or otherwise adversely impact downstream processing. A sacrificial protective layer including an SRP can be added to the substrate prior to exposure to ambient conditions. In some examples, the sacrificial protective layer is applied in the substrate processing tool prior to transferring the substrate to the substrate buffer for storage or to another substrate processing tool. In other examples, the sacrificial protective layer is applied in another processing chamber (not associated with the substrate processing tool). For example, an SRP and one or more cap layers may be added in a substrate processing tool 402b.

Prior to performing another treatment on the substrate, the sacrificial protective layer is removed as described herein. For example, the substrate may be transferred to the substrate processing tool 402b after a period of storage in the substrate buffer 430 or after processing in the substrate processing tool 402a. The sacrificial protective layer may be removed in one of the processing chambers in the substrate processing tool 402b, or another processing chamber (not associated with the substrate processing tool 802b). In some embodiments, the sacrificial protective layer is removed in a load lock 420.

In some examples, the sacrificial protective layer is applied by a processing chamber in the same substrate processing tool (that performed substrate treatment) prior to exposure to ambient conditions. Since the substrate processing tool operates at vacuum, exposure of the substrate to ambient conditions is prevented. In some examples, the sacrificial layer is deposited after a wet clean process. In this case, oxides and residues may be removed by the wet clean process and the sacrificial layer is deposited in sequence prior to drying the wafer or immediately after drying the wafer. In some examples, this process is not done under vacuum and is done without any exposure of the dry pristine surface to the ambient. In other examples, the substrate is transported from the substrate processing tool to another processing chamber located outside of the substrate processing tool that adds the sacrificial protective layer. Using this approach limits or reduces the period of exposure of the substrate to ambient conditions. Exposure is limited to a brief period of transport from the substrate processing tool to the processing chamber where the sacrificial protective layer is applied. Storage of the substrate may be performed for longer periods without additional exposure to ambient conditions. Subsequently, the sacrificial protective layer may be removed prior to further processing. In some examples, the sacrificial protective layer is removed in another substrate processing tool under vacuum conditions prior to substrate treatment in processing chambers of the same substrate processing tool. In other examples, the substrate is transported to a processing chamber that removes the sacrificial protective layer and then to the substrate processing tool for further processing. This approach also limits exposure to ambient conditions between the processing chamber and the substrate processing tool or other environment. In one example, the sacrificial protective layer is formed immediately after etch, deposition, or other process by exposing the substrate to a small molecule vapor that condenses on the surface to form a film. This can be performed directly inside the tool in which the etch or deposition occurred (e.g., substrate processing tool 402a) and may occur in the same processing chamber in which the etch or deposition occurred. The substrate is then taken to the next tool for processing (e.g., substrate processing tool 402b). Once the substrate is again no longer exposed to ambient conditions (for example by bringing the substrate under vacuum or an atmosphere purged with an inert gas), vacuum and compounds, and in some cases, other stimuli, as described above are applied to induce the film to degrade and be removed from the substrate. This may take place inside of a processing chamber as described above (e.g., process chamber 404a of substrate processing tool 402b).

In various embodiments, a system controller is employed to control process conditions during processing including during the SRP removal. The controller will typically include one or more memory devices and one or more processors. A processor may include a CPU or computer, analog and/or digital input/output connections, stepper motor controller boards, etc.

The controller may control all the activities of a removal apparatus. The system controller executes system control software, including sets of instructions for controlling the timing, mixture of gases, chamber pressure, chamber temperature, wafer temperature, wafer chuck or pedestal position, plasma power, and other parameters of a particular process. Other computer programs stored on memory devices associated with the controller may be employed in some embodiments.

Typically, there will be a user interface associated with the controller. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the reactant pulses and purge gas flows and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, substrate temperature, and plasma power. These parameters are provided to the user in the form of a recipe and may be entered utilizing the user interface.

Signals for monitoring the process may be provided by analog and/or digital input connections of the system controller. The signals for controlling the process are output on the analog and digital output connections of the system.

The system software may be designed or configured in many ways.

For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. The parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a PVD chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck. A plasma power program may control plasma power.

Examples of chamber sensors that may be monitored during removal include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically comprises some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### Examples

Diethyl phthalate (DEP) plasticizer was added to poly(phthaldehyde)-co-ethanal (PPHA-co-EA) SRP to make an SRP formulation. PPHA-co-EA has a degradation temperature of about 150° C., lower than its glass transition temperature (Tg). When baked, PPHA-co-EA degrades before it reaches its Tg. The below table shows Tg as a function DEP concentration. The pphr is calculated as (mass of plasticizer/mass of SRP)*100.

| DEP pphr | Tg |
|---|---|
| 4.8 | 114 |
| 9 | 109 |
| 13 | 108 |
| 22 | 102 |

Glass transition temperature is linearly correlated with DEP concentration. In the above example, 7-9 pphr DEP may be used for a Tg of about 110°−112° C., allowing an acid degradation process temperature of about 105° C. after a bake at 115° C. —well below the onset degradation temperature. (In the above example, zero DEP also resulted in a depressed Tg, which may have been an artifact of the measurement process or due to residual solvent within the film.) The results show that Tg may be controlled precisely with the addition of a plasticizer.

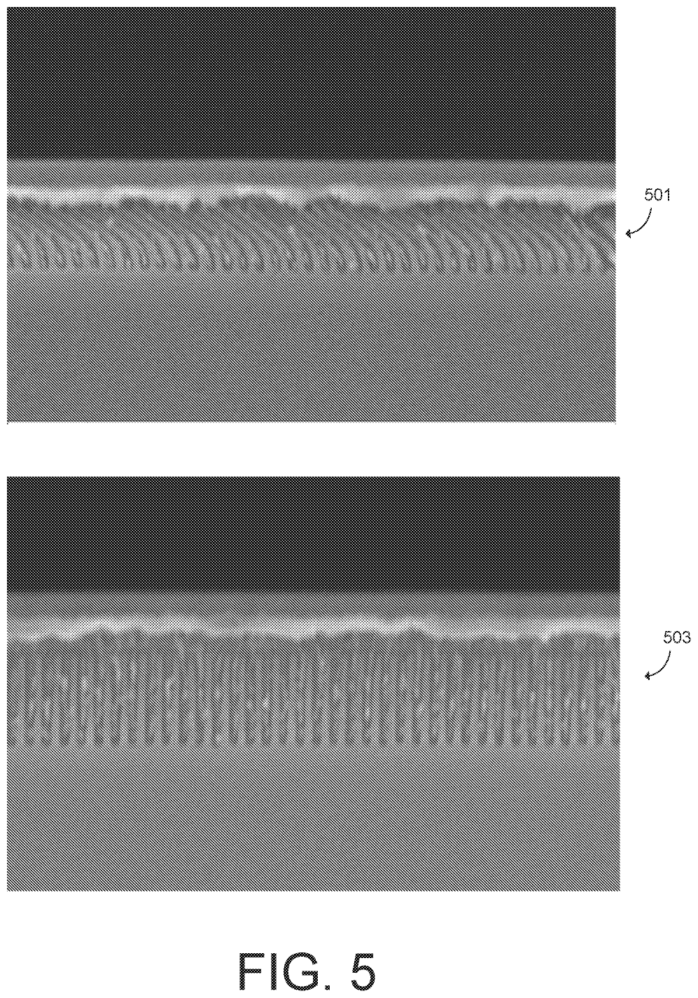

FIG. 5 shows images of an SRP formulation including PPHA-co-EA and DEP after spin coating into a high aspect ratio structure (image 501) and after baking at 115° C. (image 503). The structure after spin coating shows severe bending, which is removed by baking without degrading the polymer.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method comprising:
providing a substrate with an SRP film thereon, wherein the SRP film comprises a stimulus responsive polymer (SRP), the SRP characterized by a ceiling temperature (Tc) at which the SRP is in thermal equilibrium with its monomers, the T_{c} being between −80° C. and 400° C.; and
baking the SRP film at a baking temperature, wherein the baking temperature is below a degradation temperature of the SRP and above a glass transition temperature of the SRP film.

2. The method of claim 1, wherein the SRP is amorphous.

3. The method of claim 1, wherein the SRP is semi-crystalline or crystalline and the baking temperature is above a melting temperature of the SRP film.

4. The method of claim 1, wherein the substrate has a high aspect ratio (HAR) structure having gaps formed between features and wherein the SRP film is provided in the gaps.

5. The method of claim 4, wherein baking the SRP film straightens the HAR structure.

6. The method of claim 1, wherein providing the substrate with the SRP film comprises spin coating an SRP formulation on the substrate.

7. The method of claim 6, wherein the substrate has a high aspect ratio (HAR) structure, the HAR structure comprising gaps between features, and wherein spin coating the SRP formulation on the substrate comprises filling the gaps with the SRP film and bending the features of the HAR structure.

8. The method of claim 7, wherein baking the SRP film straightens the features of the HAR structure.

9. The method of claim 1, wherein the SRP film comprises a plasticizer.

10. The method of claim 9, wherein the (mass of plasticizer/mass of SRP)*100 is between 1 and 35.

11. The method of claim 1, wherein the SRP comprises a poly(phthalaldehyde) or a derivative thereof as a homopolymer or as one of the constituent polymers of a copolymer.

12. The method of claim 9, wherein the SRP film comprises a phthalate plasticizer.

13. The method of claim 1, further comprising removing the SRP film.

14. The method of claim 13, wherein removing the SRP film comprises exposing the SRP film to a stimulus depolymerize the SRP.

15. The method of claim 14, wherein the stimulus comprises heat.

16. The method of claim 14, wherein the stimulus comprises UV radiation.

17. The method of claim 14, wherein the stimulus comprises acidic vapor.

18. The method of claim 14, wherein the stimulus comprises a noble gas plasma.

19. The method of claim 1, wherein the SRP film comprises an organic weak acid.

20. The method of claim 1, wherein providing a substrate with an SRP film thereon comprises depositing the SRP film by chemical vapor deposition.

21. The method of claim 1, wherein the SRP film does not comprise a plasticizer.

22. An apparatus comprising:
a chamber for housing a substrate with an SRP film thereon, wherein the SRP film comprises a stimulus responsive polymer (SRP), the SRP characterized by a ceiling temperature (Tc) at which the SRP is in thermal equilibrium with its monomers, the T_{c} being between −80° C. and 400° C.; and a controller comprising instructions for baking the SRP film at a baking temperature, wherein the baking temperature is below a degradation temperature of the SRP and above a glass transition temperature of the SRP film.

23. The apparatus of claim 1, wherein the instructions further comprise instructions for depositing the SRP film.
